(19) United States
(12) Patent Application Publication
(10) Pub. No.: US 2023/0074247 A1
(43) Pub. Date: Mar. 9, 2023

(54) METHOD FOR MONITORING PRODUCTS FOR DEFECTS, ELECTRONIC DEVICE, AND STORAGE MEDIUM

(71) Applicants: HONGFUJIN PRECISION ELECTRONICS (CHENGDU) Co., Ltd., Chengdu (CN); HON HAI PRECISION INDUSTRY CO., LTD., New Taipei (TW)

(72) Inventors: ZI-QING XIA, Chengdu (CN); LI WAN, Chengdu (CN); CHENG-YONG ZHENG, Chengdu (CN); LI HUANG, Chengdu (CN); DONG CHEN, Chengdu (CN); ZHEN-XIN DENG, Chengdu (CN); XIN ZHOU, Chengdu (CN); LIN-KUAN LU, Chengdu (CN); MENG WANG, Chengdu (CN); XIA LUO, Chengdu (CN); XIAO-MEI MA, Chengdu (CN)

(21) Appl. No.: 17/897,542

(22) Filed: Aug. 29, 2022

(30) Foreign Application Priority Data
Sep. 7, 2021 (CN) 202111043059.5

(51) Int. Cl. G01R 31/28

(52) U.S. Cl. CPC G01R 31/2801

(57) ABSTRACT

A method for monitoring defects of a product implemented in an electronic device obtains product data in real time and determines whether a product is defective based on the product data; when the product is defective, outputting first warning information based on the number of defects of the product which satisfy a first preset condition; obtaining a rate of defects of the product every first preset time period, and outputting second warning information based on the rate of defects of the product when the rate of defects satisfies at least one of a second, third, and fourth preset conditions; when any warning information is output, analyzing distribution of the defects of the product; and predicting at least one cause of each defect of the product according to historical maintenance data of the product and a self-learning record of the electronic device.

### FIELD

The subject matter herein generally relates to quality control, and particularly to an electronic device, a method for monitoring products for defects, and a storage medium.

### BACKGROUND

Products, such as SMT chips and circuit boards, have the manufacturing requirements of high assembly density, small size, and light weight. However, a large number of test stations means that problems such as discrete data, message lag, batch quality abnormalities that cannot be handled in time, and identification of true cause. To avoid these problems, manufacturers rely on staff's experience, which may not be effective to warn of product defects in real time, or produce early warning threshold conditions. Relying on staff experience to make adjustments is inefficient and costly, the yield and quality of finished products can be very low.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a block diagram of an embodiment of application environment of a method for monitoring products for defects according to the present disclosure.

FIG. 2 illustrates a flowchart of an embodiment of a method for monitoring products for defects according to the present disclosure.

FIG. 3 is a schematic view of an embodiment of product yield control according to the present disclosure.

FIG. 4 is a block diagram of an embodiment of an electronic device according to the present disclosure.

### DETAILED DESCRIPTION

Multiple embodiments are described in the present disclosure, but the description is exemplary rather than limiting, and there may be more embodiments and implementation solutions within the scope of the embodiments described in the present disclosure. Although many possible combinations of features are shown in the drawings and discussed in the detailed description, many other combinations of the disclosed features are also possible. Unless specifically limited, any feature or component of any embodiment may be used in combination with or in place of any other feature or component of any other embodiment.

When describing representative embodiments, the specification may present methods and/or processes as a specific sequence of steps. However, to the extent that the method or process does not depend on the specific order of steps described in the present disclosure, the method or process should not be limited to the specific order of steps described. As understood by those of ordinary skills in the art, other orders of steps are also possible. Therefore, the specific order of steps set forth in the specification should not be interpreted as limitation to the claims. In addition, the claims for the method and/or process should not be limited to the steps performed in the written order, and those of skill in the art may readily understand that these orders may vary and still remain within the essence and scope of the embodiments of the present disclosure.

Unless otherwise defined, technical terms or scientific terms used in the embodiments shall have common meanings as construed by those of ordinary skill in the art to which the present disclosure pertains. The terms “first”, “second” and the like used in the embodiments of the present disclosure do not represent any order, quantity or importance, but are merely used to distinguish among different components. The terms “include”, “contain” or the like mean that components or articles appearing before the words cover components or articles listed after the words and their equivalents, without excluding other components or articles. The words “connect”, “link” or the like are not limited to physical or mechanical connection, but may include electrical connections, whether direct or indirect.

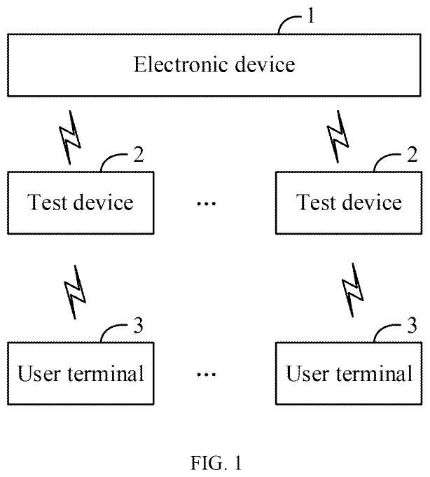

Referring to FIG. 1, a schematic view of application environment of a method for monitoring products for defects is shown.

The method for monitoring defects of products is applied in an electronic device 1, the electronic device 1 communicates with a number of test devices 2 and a user terminal 3 through a network. The network may be a wired network, such as a bus, or a wireless network, such as radio, WI-FI, cellular, satellite, broadcast, and the like. The cellular network can be a 4G network or a 5G network.

The electronic device 1 may be an electronic device having a defect monitoring program installed, such as a personal computer, a server, and the like, the server may be a single server, a server cluster, or the like.

The test device 2 may be a device for testing products. The user terminal 3 can be a smart phone, a personal computer, or a personal data assistant.

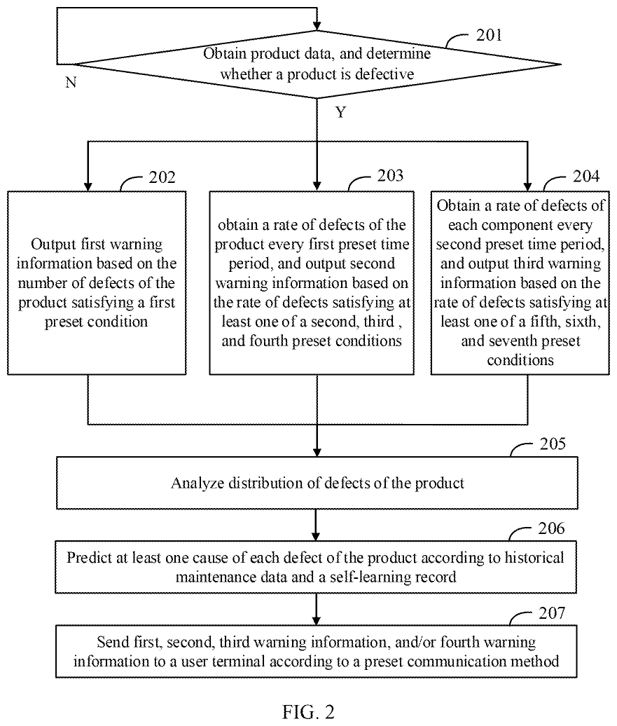

FIG. 2 illustrates a flowchart of an embodiment of a method for monitoring products for defects. The method is provided by way of example, as there are a variety of ways to carry out the method. Each block shown in FIG. 2 represents one or more processes, methods, or subroutines carried out in the example method. Furthermore, the illustrated order of blocks is by example only and the order of the blocks can be changed. Additional blocks may be added or fewer blocks may be utilized, without departing from this disclosure. The example method can begin at block 201.

At block 201, obtaining product data in real time, and determining whether the product is defective based on the product data.

In one embodiment, obtaining product data in real time includes: obtaining test data of a product from the test device 2 where the product is located. The product data includes, but is not limited to, a serial number of the product, test values, a serial number of the test device, and maintenance data. In one embodiment, the products may be printed circuit boards, and the test device 2 may be an SMT (Surface Mounted Technology) test device.

In one embodiment, determining whether the product is defective based on the product data includes: comparing a test value in the obtained product data with a corresponding threshold, if the test value is greater than the threshold, it is determined that the product is defective, and the process goes to block 202, if the test value is less than or equal to the threshold, it is determined that the product is not defective and the process continues to block 201.

In other embodiments, the product data is input into a defect detection model. The product defect detection model may be a neural network model established by training based on historical data as to defects in multiple dimensions of the product. Whether the product is defective is determined by analyzing the product data through the defect detection model. The defect detection model extracts the features of the product data, classifies the features of the product data, and determines whether the features of the product data belong to the features of the data of the defective product. When it is determined that the features of the product data belongs to or is included in the features of the data of the defective product, the product is determined to be defective. When it is determined that the features of the product data does not belong to or is not included in the features of the data of the defective product, the product is determined to be not defective.

Further, if it is determined that the product is defective, it is determined that the test item corresponding to the generation of the product data is a defective item. For example, if the product data is data as to the size or abrasion data of the product, the defective item is determined to be an appearance test item.

At block 202, when it is determined that the product is defective, outputting first warning information based on the number of defects of the product that satisfies a first preset condition.

In one embodiment, the first preset condition includes the number of defects generated in a first preset period being greater than or equal to a first threshold, the number of defects of a defective item in the first preset period being greater than or equal to a second threshold, the number of machines outputting the products with defects being greater than or equal to a third threshold, the rate of defects being greater than a mean value, and the number of defects in a same manufacturing line being less than a fourth threshold. The machines and the manufacturing line are used for manufacturing the products.

In one embodiment, the first preset time period may be four hours, the first threshold may be 100, the second threshold may be 8, the third threshold may be 3, and the mean value may be 0.08%, the fourth threshold may be 12. In one embodiment, the first warning information is used to warn that the number of defects of the products is abnormal.

In one embodiment, the method further includes: outputting the first warning information based on the number of defects of the product satisfying an eighth preset condition.

The eighth preset condition includes the number of defects in the first preset time period being less than the first threshold, the number of defects in the defective item in newly produced preset quantity of products being greater than or equal to the second threshold, and the number of machines outputting products with defects being greater than or equal to the third threshold, the rate of defects being greater than the mean value, and the number of defects in the same manufacturing line being less than the fourth threshold. In one embodiment, the preset quantity may be 100.

In one embodiment, the method further includes: outputting fourth warning information based on the number of defects of the products satisfying a ninth preset condition.

The ninth preset condition includes the number of defects of the products in the first preset time period being greater than or equal to the first threshold, the number of defects in the defective item in the first preset time period being greater than or equal to the second threshold, the number of machines outputting products with defects being greater than or equal to the third threshold, the rate of defects being greater than the mean value, and the number of defects in the same manufacturing line being greater than or equal to the fourth threshold.

In one embodiment, the method further includes: outputting the fourth warning information based on the number of defects of the products satisfying a tenth preset condition.

The tenth preset condition includes the number of defects of the products in the first preset time period being less than the first threshold, the number of defects in the defective item in the newly produced preset quantity of products being greater than or equal to the second threshold, the number of machines outputting products with defects being greater than or equal to the third threshold, the rate of defects being greater than the mean value, and the number of defects in the same manufacturing line being greater than or equal to the fourth threshold.

At block 203, obtaining a rate of defects of the product every first preset time period, and outputting second warning information based on the rate of defects of the product satisfying at least one of the second, third, and fourth preset conditions.

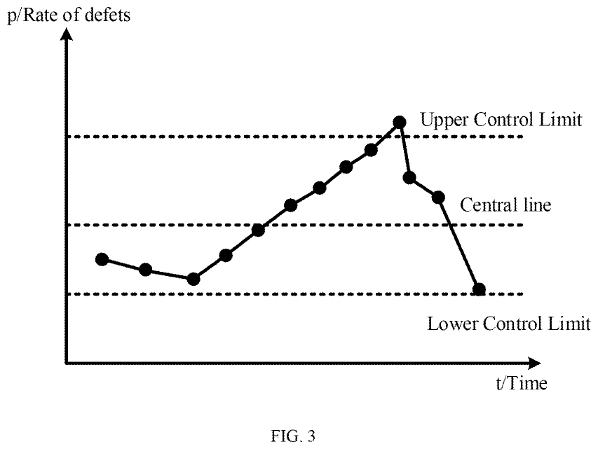

In one embodiment, the second preset condition includes the rate of defects being greater than a control threshold within a second preset time period, the rate of defects being greater than a fifth threshold, the number of defects being greater than or equal to a sixth threshold, and the number of produced products being greater than or equal to a seventh threshold. The control threshold can be the upper control limit in FIG. 3.

The third preset condition includes a consecutive eighth threshold number of points in a control chart (P-chart) of rate of defects exceeding a median, and the number of defects being greater than or equal to a ninth threshold. The central line in FIG. 3 represents the median.

The fourth preset condition include a consecutive tenth threshold number of points rising in the control chart of rate of defects.

In one embodiment, the second warning information is used to warn that the rate of defects of the products is abnormal.

In one embodiment, the first preset period may be one day, the second preset time period may be 30 days, the control threshold may be 0.15%, the fifth threshold may be 0.1%, the sixth threshold may be 8, the seventh threshold may be 500, the eighth threshold may be 7, the median may be 0.05%, the ninth threshold may be 8, and the tenth threshold may be 7. Referring to FIG. 3, for example, the rate of defects rises at seven consecutive points in the control chart, and the second warning information is output at this time.

At block 204, obtaining the rate of defects of each component in the product every second preset time period, and outputting third warning information based on the rate of defects of the component in the product satisfying at least one of the fifth, sixth, and seventh preset conditions.

In one embodiment, the fifth preset condition includes the rate of defects of any component being greater than the control threshold within a third preset time period, the rate of defects being greater than an eleventh threshold, the number of defects being greater than or equal to a twelfth threshold, and the number of produced products being greater than or equal to a thirteenth threshold.

The sixth preset condition includes a consecutive fourteenth threshold number of points in the P-chart exceeding the median, and the number of defects being greater than or equal to a fifteenth threshold.

The seventh preset condition include a consecutive sixteenth threshold number of points rising in the P-chart.

In one embodiment, the third warning information is used to warn that the rate of defects of the components in the product is abnormal.

In one embodiment, the second preset period may be eight hours, the third preset time period may be 30 days, the control threshold may be 0.15%, the eleventh threshold may be 0.05%, the twelfth threshold may be 5, the thirteenth threshold may be 1000, the fourteenth threshold may be 7, the median may be 0.03%, the fifteenth threshold may be 5, and the sixteenth threshold may be 7.

In one embodiment, the warning levels of the first to third warning information are the same and are lower than the warning level of the fourth warning information. In one embodiment, the warning levels of the first to third warning information are all yellow, and the warning level of the fourth warning information is red.

At block 205, after outputting any warning information, analyzing distribution of the defects of products.

In one embodiment, analyzing distribution of the defects of products includes: after outputting any warning information, analyzing the distribution of the defects of products in the test device, the distribution of the defects of products in a previous process and a current process, and the distribution of the defects of products in the test time, etc. Custom distribution analysis is supported. Users can select other distribution analysis dimensions according to actual requirements, such as the distribution of the defects of products in testers.

In detail, based on a process of the defect analysis, establishing a trend chart of the rate of defects and a distribution map of the defects, and gradually refining and analyzing relevant information including the information of the manufacturing lines, test devices, and products, obtaining a mark and description of each defect, and locating the defect in different dimensions (i.e., the distribution of the defects of products in the test device, the distribution of the defects of products in a previous process and a current process, and the distribution of the defects of products in the test time).

That is, based on the number of defects of products detected by different test devices, analyzing the distribution of defective products in the test devices. Based on the number of defects of products detected by different previous processes, analyzing the distribution of defects of products in the previous processes. Based on the number of defects of products detected by different current processes, analyzing the distribution of defects of products in the current processes. Based on the test time at which the detected defects are located, analyzing the distribution of defects of products in the test time.

At block 206, predicting at least one cause of each defect of the product according to historical maintenance data of the product and a self-learning record. The self-learning record is pre-obtained by the electronic device.

In one embodiment, predicting at least one cause of each defect of the product according to historical maintenance data of the product and a self-learning record includes:

querying the historical maintenance data for a number of causes of each defect corresponding to each defective item of the product;

querying the self-learning record for a number of causes of the defect corresponding to each defective item of the product;

predicting the at least one cause of the defect of the product according to a proportion of each cause of each defect corresponding to each defective item of the product in the historical maintenance data and the self-learning record.

The above prediction method supports the recording of manual re-judgment results and processing countermeasures, forms a closed-loop monitoring and tracking of product defects, and provides accurate data sources for manual re-judgment results required by system autonomous learning.

In detail, querying the historical maintenance data for a number of defect causes corresponding to each defective item of the product, the number of defect causes corresponding to each defective item of the product includes the defect cause each time the defective item occurs, and determining a proportion of each defect cause, and sorting the number of defect causes according to the proportion of each defect cause. In one embodiment, the proportion of defect cause is the proportion between the number of occurrences of the defect cause and the total number of occurrences of the defective item.

Further, inputting the defective item and corresponding test values into a prediction model of defect cause of a global quality control system, and outputting a number of defect causes and a probability of each defect cause through the prediction model of defect cause, so as to re-judge the defect cause, and determining the defect cause according to the proportion of each defect cause and the probability of each defect cause.

For example, sorting a number of defect causes based on a sum of the proportion and the probability of each defect cause, and marking the top three defect causes in the sorting, sending the top three defect causes a user terminal, the defect cause can further be re-judged by the user manually, and treatment countermeasures are determined according to the historical maintenance data.

In one embodiment, the prediction model of defect cause is established by a convolutional neural network being trained based on the training data including a number of defective items in the historical maintenance data, the corresponding test values of each defective item, and the defect causes of each defective item, the prediction model of defect cause is an independent learning outcome of the global quality control system. The prediction model of defect cause extracts the features of the defective item and corresponding test values, and obtains a number of defect causes by classifying the extracted features, and calculates the probability of each defect cause, that is, the likelihood of each defect cause.

In one embodiment, according to the historical maintenance data of the product and the self-learning record, the causes of defects of the product are comprehensively predicted, and manual re judgment results and treatment countermeasure determination are supported, a closed loop of self-learning thus is formed.

At block 207, sending the first warning information, the second warning information, the third warning information, and/or the fourth warning information to the user terminal 3 according to a preset communication method.

In one embodiment, the preset communication method includes, but is not limited to, web page information, application information, email, and message. When sending the warning information to the user terminal 3, the severity or level of the warning information can be indicated by a background color or a title color of the warning information. For example, red indicates very urgent, yellow indicates urgent, and blue indicates not urgent. The user of the user terminal 3 may be the person in charge of production.

Further, the method further includes: receiving offline exception handling and process improvement countermeasures sent by the user terminal 3.

In one embodiment, the offline exception handling and process improvement countermeasures are input by the user of the user terminal 3. The offline exception handling and process improvement countermeasures can automatically optimize the pre-warning and pre-judgment analysis process, and improve the pre-warning and pre-judgment accuracies based on expert experience and knowledge, so as to improve the previous processes and the current processes.

It can be understood that, the first threshold to the sixteenth threshold can be preset and adjusted according to actual requirements.

Further, the method further includes: displaying the distribution analysis result of the defects and the predicted causes of the defects of the products on a display device.

In one embodiment, the analysis results of the distribution of the test device, the distribution of the previous process and the current process, and the distribution of the test time are displayed on the display device in a form of a pie chart or a bar chart. The sorting of a number of predicted defect causes is displayed on the display device in a form of a comparison table, and the first or top three predicted defect causes are marked in the form of highlighted or prominent colors.

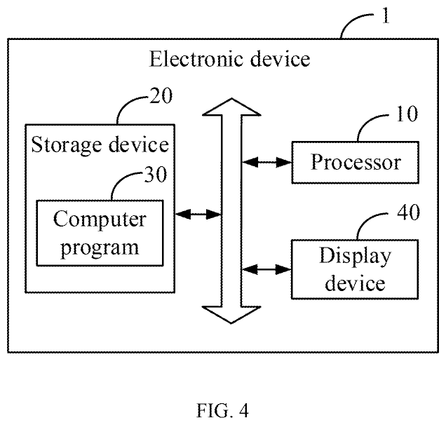

FIG. 4 illustrates the electronic device 1 in one embodiment. The electronic device 1 includes, but is not limited to, a processor 10, a storage device 20, a computer program 30, and a display device 40. The display screen 40 is a liquid crystal display (LCD) screen or an organic light-emitting semiconductor display (OLED) screen. FIG. 4 illustrates only one example of the electronic device 1. Other examples can include more or fewer components than as illustrated or have a different configuration of the various components in other embodiments.

The processor 10 can be a central processing unit (CPU), a microprocessor, or other data processor chip that performs functions in the electronic device 1.

In one embodiment, the storage device 20 can include various types of non-transitory computer-readable storage mediums. For example, the storage device 20 can be an internal storage system, such as a flash memory, a random access memory (RAM) for the temporary storage of information, and/or a read-only memory (ROM) for permanent storage of information. The storage device 20 can also be an external storage system, such as a hard disk, a storage card, or a data storage medium.

The storage device 20 stores instructions, the processor 10 executes the computer program 30 stored in the storage device 20 for implementing the method for monitoring products for defects provided in the embodiments of the present disclosure. The computer program 30 is product monitoring program and includes instructions.

The processor 10 is configured to:

obtain product data in real time, and determine whether the product is defective based on the product data;

when it is determined that the product is defective, output first warning information based on the number of defects of the product satisfying a first preset condition;

obtain a rate of defects of the product every first preset time period, and output second warning information based on the rate of defects of the product satisfying at least one of the second preset condition, the third preset condition, and the fourth preset condition;

obtain a rate of defects of each component in the product every second preset time period, and output third warning information based on the rate of defects of the component in the product satisfying at least one of the fifth, sixth, and seventh preset conditions;

after outputting any warning information, analyze distribution of the defects of products;

predict the cause of the defect of the product according to the historical maintenance data of the product and the self-learning record;

send the first warning information, the second warning information, the third warning information and/or the fourth warning information to the user terminal 3 according to a preset communication method.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being embodiments of the present disclosure.

What is claimed is:

1. A method for monitoring products for defects implemented in an electronic device comprising:
obtaining product data in real time, and determining whether a product is defective based on the product data;
in response that the product is determined to be defective, outputting first warning information based on the number of defects of the product satisfying a first preset condition;
the first preset condition comprising the number of defects in a first preset period being greater than or equal to a first threshold, the number of defects of a defective item in the first preset period being greater than or equal to a second threshold, the number of machines outputting products with defects being greater than or equal to a third threshold, a rate of defects being greater than a mean value, and the number of defects in a manufacturing line being less than a fourth threshold;
obtaining a rate of defects of the product every first preset time period, and outputting second warning information based on the rate of defects of the product satisfying at least one of a second preset condition, a third preset condition, and a fourth preset condition;
the second preset condition comprising the rate of defects being greater than a control threshold within a second preset time period, the rate of defects being greater than a fifth threshold, the number of defects being greater than or equal to a sixth threshold, and the number of produced products being greater than or equal to a seventh threshold, the third preset condition comprising a consecutive eighth threshold number of points in a control chart of rate of defects exceeding a median, and the number of defects being greater than or equal to a ninth threshold, the fourth preset condition comprises a consecutive tenth threshold number of points raising in the control chart;
in response that any warning information is output, analyzing distribution of the defects of the product; and
predicting at least one cause of each defect of the product according to historical maintenance data of the product and a self-learning record of the electronic device.

2. The method according to claim 1, further comprising:
obtaining a rate of defects of each component in the product every second preset time period, and outputting third warning information based on the rate of defects of the component in the product satisfying at least one of a fifth, sixth, and seventh preset conditions;
the fifth preset condition comprising the rate of defects of any component being greater than the control threshold within a third preset time period, the rate of defects of any component being greater than an eleventh threshold, the number of defects of any component being greater than or equal to a twelfth threshold, and the number of produced products being greater than or equal to a thirteenth threshold, the sixth preset condition comprises a consecutive fourteenth threshold number of points in the control chart exceeding the median, and the number of defects being greater than or equal to a fifteenth threshold, the seventh preset condition comprises a consecutive sixteenth threshold number of points raising in the control chart.

3. The method according to claim 2, further comprising:
in response that the product is defective, outputting the first warning information based on the number of defects of the product satisfying an eighth preset condition;
the eighth preset condition comprising the number of defects in the first preset time period being less than the first threshold, the number of defects of the defective item in a preset number of newly produced products being greater than or equal to the second threshold, the number of machines outputting products with defects being greater than or equal to the third threshold, the rate of defects being greater than the mean value, and the number of defects in the manufacturing line being less than the fourth threshold.

4. The method according to claim 3, further comprising:
in response that the product is defective, outputting fourth warning information based on the number of defects of the product satisfying a ninth preset condition;
the ninth preset condition comprising the number of defects of the product in the first preset time period being greater than or equal to the first threshold, the number of defects of the defective item in the first preset time period being greater than or equal to the second threshold, the number of machines outputting products with defects being greater than or equal to the third threshold, the rate of defects being greater than the mean value, and the number of defects in the manufacturing line being greater than or equal to the fourth threshold.

5. The method according to claim 4, wherein the first warning information and the fourth warning information are used to warn that the number of defects of the product is abnormal, the second warning information is used to warn that the rate of defects of the product is abnormal, and the third warning information is used to warn that the rate of defects of the component in the product is abnormal.

6. The method according to claim 5, wherein warning levels of the first warning information, the second warning information, and the third warning information are the same, and are lower than a warning level of the fourth warning information.

7. The method according to claim 1, wherein analyzing distribution of the defects of the product comprises:
analyzing distribution of defects of the product in test devices, distribution of defects of the product in a previous process and a current process, and distribution of defects of the product in test time.

8. The method according to claim 1, wherein predicting at least one cause of each defect of the product according to historical maintenance data of the product and a self-learning record of the electronic device comprises:
querying the historical maintenance data for a plurality of causes of each defect corresponding to each defective item of the product;
querying the self-learning record for a plurality of causes of each defect corresponding to each defective item of the product.
predicting the at least one cause of each defect of the product according to a proportion of each cause of each defect corresponding to each defective item of the product according to the historical maintenance data and the self-learning record.

9. An electronic device comprising:
at least one processor; and
a storage device coupled to the at least one processor and storing instructions for execution by the at least one processor to cause the at least one processor to:
obtain product data in real time, and determining whether a product is defective based on the product data;
in response that the product is determined to be defective, output first warning information based on the number of defects of the product satisfying a first preset condition;
the first preset condition comprising the number of defective items in a first preset period being greater than or equal to a first threshold, the number of defects of a defective item in the first preset period being greater than or equal to a second threshold, the number of machines outputting products with defects being greater than or equal to a third threshold, a rate of defects being greater than a mean value, and the number of defects in a manufacturing line being less than a fourth threshold;
obtain a rate of defects of the product every first preset time period, and outputting second warning information based on the rate of defects of the product satisfying at least one of a second preset condition, a third preset condition, and a fourth preset condition;
the second preset condition comprising the rate of defects being greater than a control threshold within a second preset time period, the rate of defects being greater than a fifth threshold, the number of defects being greater than or equal to a sixth threshold, and the number of produced products being greater than or equal to a seventh threshold, the third preset condition comprising a consecutive eighth threshold number of points in a control chart of rate of defects exceeding a median, and the number of defects being greater than or equal to a ninth threshold, the fourth preset condition comprises a consecutive tenth threshold number of points raising in the control chart;
in response that any warning information is output, analyze distribution of the defects of the product; and
predict at least one cause of each defect of the product according to historical maintenance data of the product and a self-learning record of the electronic device.

10. The electronic device according to claim 9, wherein the at least one processor is further caused to:
obtain a rate of defects of each component in the product every second preset time period, and output third warning information based on the rate of defects of the component in the product satisfying at least one of a fifth, sixth, and seventh preset conditions;
the fifth preset condition comprising the rate of defects of any component being greater than the control threshold within a third preset time period, the rate of defects of any component being greater than an eleventh threshold, the number of defects of any component being greater than or equal to a twelfth threshold, and the number of produced products being greater than or equal to a thirteenth threshold, the sixth preset condition comprises a consecutive fourteenth threshold number of points in the control chart exceeding the median, and the number of defects being greater than or equal to a fifteenth threshold, the seventh preset condition comprises a consecutive sixteenth threshold number of points raising in the control chart.

11. The electronic device according to claim 10, wherein the at least one processor is further caused to:
in response that the product is defective, output the first warning information based on the number of defects of the product satisfying an eighth preset condition;
the eighth preset condition comprising the number of defects in the first preset time period being less than the first threshold, the number of defects of the defective item in a preset number of newly produced products being greater than or equal to the second threshold, the number of machines outputting products with defects being greater than or equal to the third threshold, the rate of defects being greater than the mean value, and the number of defects in the manufacturing line being less than the fourth threshold.

12. The electronic device according to claim 11, wherein the at least one processor is further caused to:
in response that the product is defective, output fourth warning information based on the number of defects of the product satisfying a ninth preset condition;
the ninth preset condition comprising the number of defects of the product in the first preset time period being greater than or equal to the first threshold, the number of defects of the defective item in the first preset time period being greater than or equal to the second threshold, the number of machines outputting products with defects being greater than or equal to the third threshold, the rate of defects being greater than the mean value, and the number of defects in the manufacturing line being greater than or equal to the fourth threshold.

13. The electronic device according to claim 12, wherein the first warning information and the fourth warning information are used to warn that the number of defects of the product is abnormal, the second warning information is used to warn that the rate of defects of the product is abnormal, and the third warning information is used to warn that the rate of defects of the component in the product is abnormal.

14. The electronic device according to claim 13, wherein warning levels of the first warning information, the second warning information, and the third warning information are the same, and are lower than a warning level of the fourth warning information.

15. The electronic device according to claim 9, wherein the at least one processor is further caused to:
analyze distribution of defects of the product in test devices, distribution of defects of the product in a previous process and a current process, and distribution of defects of the product in test time.

16. The electronic device according to claim 9, wherein the at least one processor is further caused to:
query the historical maintenance data for a plurality of causes of defects corresponding to each defective item of the product;
query the self-learning record for a plurality of causes of each defect corresponding to each defective item of the product.
predict the at least one cause of each defect of the product according to a proportion of each cause of each defect corresponding to each defective item of the product according to the historical maintenance data and the self-learning record.

17. A computer-readable storage medium having instructions stored thereon, when the instructions are executed by a processor of an electronic device, the processor is configured to perform a method for monitoring products for defects, wherein the method comprises:
obtaining product data in real time, and determining whether a product is defective based on the product data;
in response that the product is determined to be defective, outputting first warning information based on the number of defects of the product satisfying a first preset condition;
the first preset condition comprising the number of defects in a first preset period being greater than or equal to a first threshold, the number of defects of a defective item in the first preset period being greater than or equal to a second threshold, the number of machines outputting products with defects being greater than or equal to a third threshold, a rate of defects being greater than a mean value, and the number of defects in a manufacturing line being less than a fourth threshold;
obtaining a rate of defects of the product every first preset time period, and outputting second warning information based on the rate of defects of the product satisfying at least one of a second preset condition, a third preset condition, and a fourth preset condition;
the second preset condition comprising the rate of defects being greater than a control threshold within a second preset time period, the rate of defects being greater than a fifth threshold, the number of defects being greater than or equal to a sixth threshold, and the number of produced products being greater than or equal to a seventh threshold, the third preset condition comprising a consecutive eighth threshold number of points in a control chart of rate of defects exceeding a median, and the number of defects being greater than or equal to a ninth threshold, the fourth preset condition comprises a consecutive tenth threshold number of points raising in the control chart;
in response that any warning information is output, analyzing distribution of the defects of the product; and
predicting at least one cause of each defect of the product according to historical maintenance data of the product and a self-learning record of the electronic device.

18. The storage medium according to claim 17, wherein the method further comprises:
obtaining a rate of defects of each component in the product every second preset time period, and outputting third warning information based on the rate of defects of the component in the product satisfying at least one of a fifth, sixth, and seventh preset conditions;
the fifth preset condition comprising the rate of defects of any component being greater than the control threshold within a third preset time period, the rate of defects of any component being greater than an eleventh threshold, the number of defects of any component being greater than or equal to a twelfth threshold, and the number of produced products being greater than or equal to a thirteenth threshold, the sixth preset condition comprises a consecutive fourteenth threshold number of points in the control chart exceeding the median, and the number of defects being greater than or equal to a fifteenth threshold, the seventh preset condition comprises a consecutive sixteenth threshold number of points raising in the control chart.

19. The storage medium according to claim 18, wherein the method further comprises:
in response that the product is defective, outputting the first warning information based on the number of defects of the product satisfying an eighth preset condition;
in response that the product is defective, outputting the first warning information based on the number of defects of the product satisfying an eighth preset condition;
the eighth preset condition comprising the number of defects in the first preset time period being less than the first threshold, the number of defects of the defective item in a preset number of newly produced products being greater than or equal to the second threshold, the number of machines outputting products with defects being greater than or equal to the third threshold, the rate of defects being greater than the mean value, and the number of defects in the manufacturing line being less than the fourth threshold.

20. The storage medium according to claim 19, wherein the method further comprises:
in response that the product is defective, outputting fourth warning information based on the number of defects of the product satisfying a ninth preset condition;
the ninth preset condition comprising the number of defects of the product in the first preset time period being greater than or equal to the first threshold, the number of defects of the defective item in the first preset time period being greater than or equal to the second threshold, the number of machines outputting products with defects being greater than or equal to the third threshold, the rate of defects being greater than the mean value, and the number of defects in the manufacturing line being greater than or equal to the fourth threshold.
